(19) United States
(12) Patent Application Publication
(10) Pub. No.: US 2026/0245641 A1
(43) Pub. Date: Aug. 20, 2026

(54) SELECTIVELY TRIGGERING ADDITIONAL BLOCK ERASE OPERATIONS

(71) Applicant: Micron Technology, Inc., Boise, ID (US)

(72) Inventors: Lei Lin, Fremont, CA (US); Luis Iam, San Jose, CA (US); Guang Hu, Mountain View, CA (US); Devin Batutis, San Jose, CA (US)

(21) Appl. No.: 19/056,435

(22) Filed: Feb. 18, 2025

(51) Int. Cl. G11C 16/34; G11C 16/16; G11C 16/26

(52) U.S. Cl. CPC G11C 16/344; G11C 16/16; G11C 16/26

(57) ABSTRACT

A system and method are provided for retiring blocks in a memory device. The system and method perform a first select gate (SG) scan operation on a memory portion of a memory device that has been erased according to a first type of erase operation. The system and method, in response to determining that the memory portion fails the first SG scan operation, perform a second SG scan operation on the memory portion, the second SG scan operation having different verification operations than the first SG scan operation. The system and method selectively perform a second type of erase operation on the memory portion based on a result of performing the second SG scan operation on the memory portion.

### TECHNICAL FIELD

This disclosure relates generally to memory sub-systems and, more specifically, to providing adaptive media management for memory components, such as memory dies.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 illustrates diagrams of different results of performing SG scan operations, in accordance with some examples.

FIG. 3 illustrates a diagram of applying adjustment factors to a second SG scan operation, in accordance with some examples.

FIG. 4 illustrates a diagram of operations performed using the media operations manager, in accordance with some examples.

FIG. 5 illustrates a diagram of operations performed using the media operations manager, in accordance with some examples.

FIG. 6 is a block diagram of an example computer system, in accordance with some examples.

### DETAILED DESCRIPTION

The present disclosure configures a memory sub-system controller to perform selection of special erase operations when retiring blocks (e.g., adding blocks to a grown bad block (GBB) pool) in a memory device. Specifically, when monitoring a portion of the memory device, the controller performs a first Select Gate (SG) scan operation to determine if voltage thresholds are within a safe range. For blocks (e.g., in the portion) that fail the first SG scan, the controller performs a second SG scan operation with different verification criteria. The controller can perform special erase operations based on the results of the two SG scan operations, where blocks failing both scans undergo special erase before retirement. This approach prevents leakage issues while optimizing system performance by avoiding performing unnecessary special erase operations. Additionally, the system may optionally incorporate temperature-based adjustments to further optimize the verification criteria. When temperature optimization is enabled, the controller can determine the current operating temperature and calculate a ratio between a base temperature and the current temperature to adjust the verification criteria. The controller can then apply specific verify levels retrieved from a lookup table that accounts for temperature factors, with verify levels being adjusted based on the temperature ratio. In this way, the memory sub-system balances reliability and performance by using dual SG scan operations to make smart decisions about when to trigger special erase operations, with temperature-based adjustments serving as an optional enhancement to further optimize the verification process. This improves the overall efficiency of operating the memory sub-system.

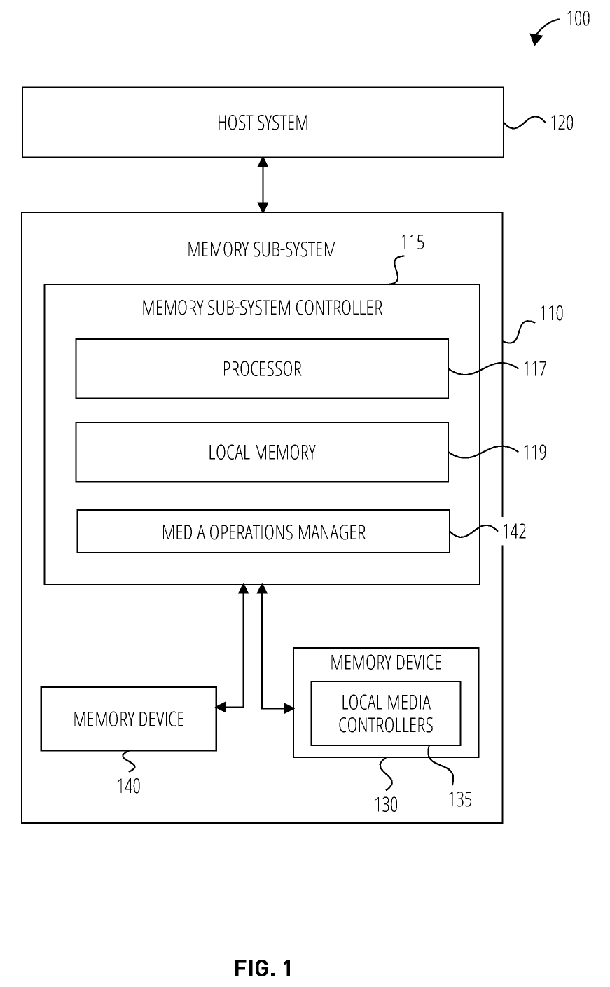

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as "garbage collection data". “User data” can include host data and garbage collection data. "System data" hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are raw memory devices combined with a local embedded controller for memory management within the same memory device package.

There are challenges in efficiently managing or performing media management operations on typical memory devices. In conventional systems, special erase operations play an important role in managing blocks that fail SG scans. A special erase operation is a process that, instead of leaving a retired block in an erased state, puts the block into a slightly programmed state. A "slightly programmed state" refers to when the voltage threshold (VT) of the block is programmed to a level that is higher than an erased state but not as high as a fully programmed state. This programming is specifically done to cut off potential leakage current that could flow through the select gates (e.g., of the transistors) and impact other good blocks operating in the same plane. The purpose of this slightly programmed state is to prevent leakage issues that would occur if the block were left in a completely erased state. When blocks with low SG voltage thresholds are retired in an erased state, they can create leakage paths that affect neighboring blocks. By programming to this intermediate state during the special erase operation, the system ensures sufficient voltage threshold levels to prevent such leakage while retiring the block. This slightly programmed state is achieved through the special erase operation, which can take approximately 5 milliseconds to complete.

In conventional systems, special erase operations are often triggered indiscriminately, leading to significant performance impacts and resource waste. Some systems blindly skip these operations, potentially causing dangerous leakage issues, while others take the opposite approach by always enabling special erase when SG scans fail at low voltage thresholds. This can result in unnecessary performance penalties since some blocks may still have sufficient voltage levels to prevent leakage. Some memory devices address these issues by implementing SG touch-up (TU) operations, but this approach has some drawbacks. Even after TU operations are performed, the memory sub-system may disable special erase operations based on potentially faulty assumptions about voltage threshold levels. This raises the risk of leakage issues that could compromise data integrity.

The lack of temperature-aware verification criteria in conventional systems further compounds these inefficiencies. Without accounting for operating temperature variations, systems may make poor decisions about special erase operations, as voltage thresholds that are sufficient at one temperature may lead to leakage issues at higher temperatures.

The present disclosure addresses these technical challenges in memory systems by providing a memory sub-system controller that performs intelligent selection of special erase operations using a dual-SG scan approach. The controller can first perform a first SG scan operation to determine if voltage thresholds are within a safe range, and upon failure, conducts a second SG scan operation with different verification criteria. This approach prevents blindly skipping or unnecessarily triggering special erase operations, which can take significantly longer (5 milliseconds) compared to SG scans (50 microseconds). The controller can optionally incorporate temperature-based adjustments by calculating ratios between base and current temperatures to further optimize verification criteria through a lookup table. By selectively performing special erase operations only when necessary, the controller effectively balances system reliability and performance while preventing leakage issues that could impact other blocks in the same plane. This intelligent approach ensures blocks are properly programmed to an intermediate state when needed, while avoiding the performance penalties associated with unnecessary special erase operations.

In some examples, a memory system performs intelligent management of erase operations through a multi-stage SG scanning process. The memory system includes a memory device, and a processing device operatively coupled to the memory device. The processing device performs operations including a first SG scan operation on a memory portion that has been erased according to a first type of erase operation. When the memory portion fails the first SG scan operation, the processing device performs a second SG scan operation with different verification operations, and selectively performs a second type of erase operation based on the second scan's results.

The verification operations between the two SG scans differ in specific ways. The second SG scan operation may use either a smaller threshold number of passing memory cells or apply a different read threshold voltage to the memory portion. During the first SG scan, the processing device applies a first verify voltage level, reads data from the memory portion, measures the number of successfully read cells, and compares this number against a first threshold to determine scan failure. For the second SG scan, the processing device applies a second verify voltage level that is lower than the first verify voltage level. The processing device then reads additional data, measures the number of successfully read cells, and compares this count against a second threshold. Passing or failing of the SG scan is determined based on whether the number of successfully read cells transgresses (e.g., exceeds) the corresponding threshold or not.

The two types of erase operations serve distinct purposes. The first type leaves none of the memory portion in a programmed state, while the second type comprises a special erase operation that programs specified regions into a programmed state. When the memory portion passes the second SG scan operation, the processing device categorizes the memory portion as a GBB without performing the second type of erase operation. Conversely, if the memory portion fails the second scan, the processing device performs the second type of erase operation before categorizing the memory portion as a GBB. The second type of erase operation specifically programs the memory portion to prevent leakage current from impacting operations of other memory portions.

In some cases, the processing device can adjust verification operations based on the current temperature of the memory device. This involves calculating a ratio between base and current temperatures using a lookup table that associates different temperature ratios with specific factors. These factors can be used to adjust either the verify level for the second SG scan operation or the minimum number of passing memory cells required. The processing device may adjust both the verify voltage level and threshold number of passing cells based on the temperature ratio between current operating temperature and base temperature.

These operations are particularly relevant for three-dimensional (3D) NAND devices, where the memory portion comprises a block of the device.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

In some examples, the memory device 130, including one or more portions (e.g., one or more WLs, one or more WLGs, one or more blocks, one or more memory dies, and/or one or more pages) or group of memory components including the memory device 130, can be associated with a first reliability (capability) grade, value, measure, or lifetime PEC. The terms “reliability grade,” “value” and “measure” are used interchangeably throughout and can have the same meaning. The memory device 140 (e.g., one or more WLs, one or more WLGs, one or more blocks, one or more memory dies, and/or one or more pages) or group of memory components, including the memory device 140, can be associated with a second reliability (capability) grade, value, measure, or lifetime PEC. In some examples, each memory component (memory device 130 and memory device 140) can store respective configuration data that specifies the respective reliability grade and lifetime PEC and current PEC and/or other conditions. In some examples, a memory or register can be associated with all of the memory components (memory device 130 and memory device 140) and can store a table that maps different groups, portions, bins or sets of the memory device 130 and memory device 140 to respective reliability grades, conditions, lifetime PEC values, and/or current PEC values.

The memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory modules (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells (e.g., including multi-level cell storage), such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or block stripes (BSs). As used herein, a block comprising SLCs can be referred to as a SLC block, a block including MLCs can be referred to as an MLC block, a block comprising TLCs can be referred to as a TLC block, and a block comprising QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing GC operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., LBA, namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (MNAND) device. Any operation discussed as being performed by the memory sub-system controller 115 can be similarly performed by the local media controllers 135 and vice versa.

The media operations manager 142 can perform selection of special erase operations when retiring blocks in the memory device 130. Specifically, when monitoring a portion of the memory device, the media operations manager 142 performs a first SG scan operation to determine if voltage thresholds are within a safe range. For blocks that fail the first SG scan operation, the media operations manager 142 performs a second SG scan operation with different verification criteria. The media operations manager 142 can perform special erase operations based on the results of the two SG scan operations, where blocks failing both scans undergo special erase before retirement. Additionally, the media operations manager 142 can optionally incorporate temperature-based adjustments by calculating ratios between base and current temperatures to optimize verification criteria through a lookup table. This intelligent approach ensures blocks are properly programmed to an intermediate state when needed, while avoiding the performance penalties associated with unnecessary special erase operations.

Any discussion with respect to the memory device 130 can similarly be applied to the memory device 140. Any function pertaining to the local media controllers 135 can, in some cases, be performed by the device) memory sub-system controller 115.

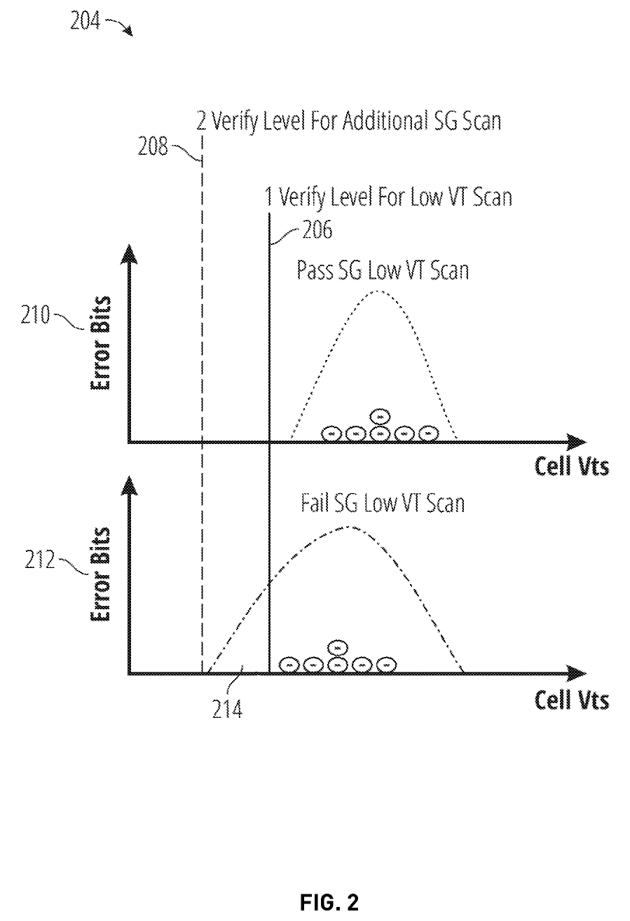

FIG. 2 illustrates diagrams of different results of performing SG scan operations, in accordance with some examples. Specifically, the media operations manager 142 can receive a request to erase a portion of the memory device 130, such as a memory block. In such cases, the media operations manager 142 can erase the memory block according to a first erase scheme or process in which all portions of the memory block are set to an erased state leaving no portion in a programmed state.

The media operations manager 142 can then determine whether the memory block is bad before returning the block for programming. The media operations manager 142 can perform a first SG operation on the memory block. Specifically, as shown in the diagram 204, as part of performing the first SG operation, the media operations manager 142 can apply a first verify voltage level 206 to the memory block to determine if the voltage thresholds of the memory cells are within a safe range. As shown in diagram 210, when the number of cells that pass the first verify voltage level exceeds a threshold number, the memory block passes the first SG scan operation.

However, as shown in diagram 212, when the number of cells that pass the first verify voltage level fails to exceed the threshold number, the memory block fails the first SG scan operation. In such cases, the media operations manager 142 performs a second SG scan operation using a second verify voltage level 208 that is lower than the first verify voltage level 206. The number of cells being read 214 represents the distribution of cell voltage thresholds (Cell Vts) that are measured during the second SG scan operation. When performing either the first or second SG scan operation, the media operations manager 142 measures this number to determine how many memory cells successfully pass the respective verify voltage levels. For the first SG scan, the system counts how many cells pass the higher verify voltage level 206, while for the second SG scan, it counts how many cells pass the lower verify voltage level 208. The scan is considered successful only if the number of cells passing the verify level exceeds a predetermined threshold number. This predetermined threshold number can be the same for the first SG scan operation and the second SG scan operation. In some cases, the first SG scan operation uses a first predetermined threshold number that is different (greater than or less than) the second predetermined threshold number used by the second SG scan operation. In this way, the second SG scan operation uses different verification criteria than the first SG scan operation. This measurement of passing cells is used for determining whether the block requires special erase operations before being categorized as a GBB.

The error bits shown in diagrams 210 and 212 represent the distribution of cell voltage thresholds (Cell Vts) across the memory block. The media operations manager 142 uses these distributions to determine whether sufficient cells pass the respective verify voltage levels to consider the scan successful. When the second SG scan fails, indicating insufficient cells pass even the lower verify voltage level, the media operations manager 142 performs a special erase operation before categorizing the block as a GBB.

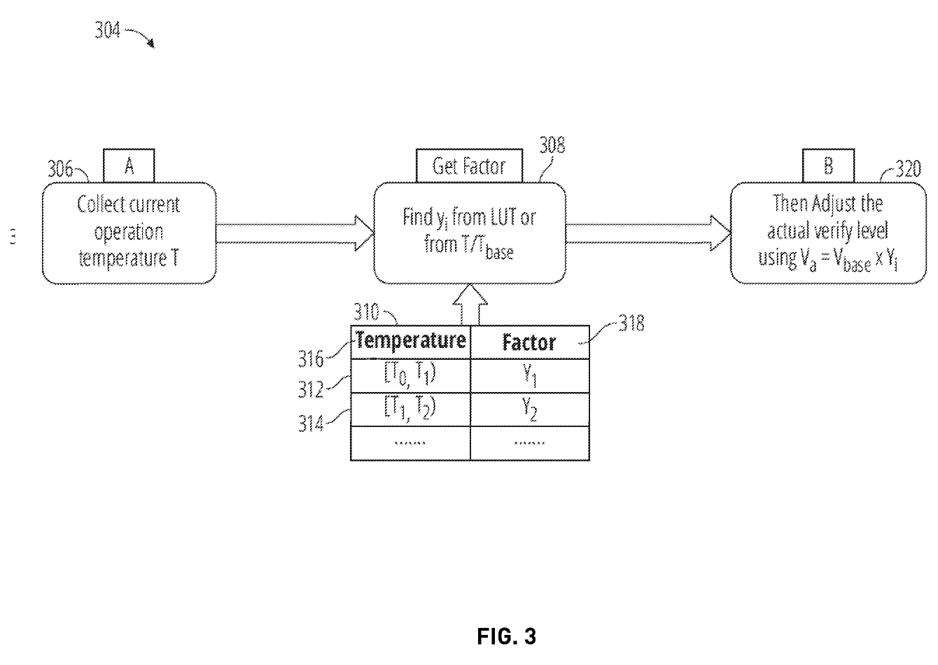

In some cases, the predetermined threshold number that is used by the second SG scan can be based on a current operating temperature of the memory device 130. Additionally, or alternatively, in some cases, the second verify voltage level 208 that is applied by the media operations manager 142 to perform the second SG scan operation can be based on the current operating temperature of the memory device 130. The media operations manager 142 can access a lookup table (e.g., as shown in FIG. 3) to obtain an adjustment factor that is applied to the parameters or verification criteria (e.g., the verify voltage level and/or the predetermined number of passing cells) of the second SG scan.

FIG. 3 illustrates a diagram 304 of applying adjustment factors to a second SG scan operation, in accordance with some examples. The media operations manager 142 can perform a series of operations to optimize verification levels of the first and/or second SG scan based on temperature conditions. Namely, at operation 306, the media operations manager 142 begins the process of obtaining adjustment factors for the verification operations of the second SG scan. This initiates the temperature-based optimization sequence for the second SG scan.

In operation 308, the media operations manager 142 collects the current operation temperature (T) of the memory device 130. This temperature measurement provides data for determining how to adjust the verification criteria. The media operations manager 142 then proceeds to operation 308, where it accesses a lookup table 310 that contains different temperature factors. This lookup table 310 associates various temperature ranges with specific adjustment factors that will be used to modify the verification operations.

The lookup table 310 includes multiple entries, such as a first entry 312 which associates a first temperature range [T₀, T₁) (which can alternatively be represented as a first ratio of a current temperature measurement to an ambient temperature) with a first factor Y₁ (e.g., the adjustment factor 318). The lookup table 310 includes a second entry 314 which associates a second temperature range [T₁, T₂) (which can alternatively be represented as a second ratio of a current temperature measurement to an ambient temperature) with a second factor Y₂.

At operation 320, the media operations manager 142 determines the appropriate factor (Yi) from the lookup table 310 based on the current temperature measurement obtained at operation 306. This factor is found either directly from the lookup table 310 (e.g., by finding the range within which the current temperature measurement falls) and/or calculated as a ratio between the current temperature (T) and a base temperature (Tbase). Once the appropriate factor is determined, the media operations manager 142 uses the adjustment factor to adjust the actual verify level (Va) by multiplying a base verify level (Vbase) by the selected factor (Yi). This calculation produces the final verify level that will be used for the second SG scan operation. In some cases, once the appropriate factor is determined, the media operations manager 142 uses the adjustment factor to adjust the predetermined number of cells of the second SG scan that are needed to pass the second SG scan by multiplying a base predetermined number of cells of the second SG scan by the selected factor (Yi). This calculation produces the final predetermined number of cells of the second SG scan that will be used for the second SG scan operation.

The temperature ranges in the lookup table 310 can be defined to ensure appropriate adjustments across different operating conditions. The first range [T₀, T₁) represents lower temperature operations, while subsequent ranges cover higher temperature scenarios. Each factor (Y₁, Y₂) in the lookup table can be calibrated to provide optimal verification levels for its corresponding temperature range. These factors help ensure that the verification criteria remain effective across varying operating conditions.

The media operations manager 142 uses these temperature-adjusted verification levels to make more informed decisions about when to trigger special erase operations. This helps prevent both under-triggering and over-triggering of special erase operations. For lower temperature ranges [T₀, T₁), the factor Y₁ may be closer to 1, requiring less adjustment to the base verify level. This reflects the more stable voltage thresholds at lower temperatures. For higher temperature ranges [T₁, T₂), the factor Y₂ may be adjusted more significantly to account for the increased likelihood of voltage threshold variations at elevated temperatures.

The adjusted verify level (Va) produced by this process is then used by the media operations manager 142 to perform the second SG scan operation. This ensures that the verification criteria are appropriate for the current operating conditions. The temperature-based adjustment process helps optimize system performance by avoiding unnecessary special erase operations while still maintaining reliability. This is important since special erase operations take significantly longer than SG scans.

The entire process from temperature collection to verify level adjustment is designed to be efficient, adding minimal overhead to the overall block management operations while providing significant benefits in terms of reliability and performance optimization.

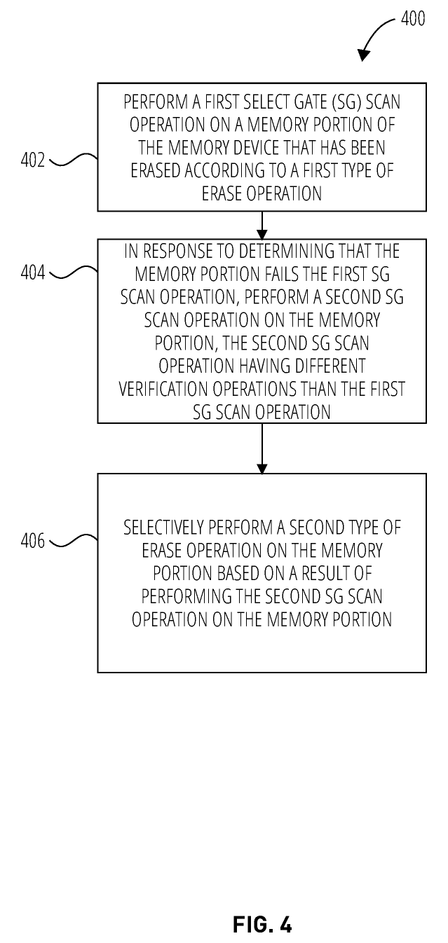

FIG. 4 illustrates a diagram 400 of operations performed using the media operations manager 142, in accordance with some examples. The method or process of diagram 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 400 is performed by the memory sub-system controller 115, local media controllers 135, and/or subcomponents of the memory sub-system controller 115 and/or local media controllers 135 of FIG. 1. In these examples, the method or process of diagram 400 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 4, the method begins at operation 402 with the media operations manager 142 performing a first SG scan operation on a memory portion of the memory device 130 that has been erased according to a first type of erase operation. At operation 404, the media operations manager 142, in response to determining that the memory portion fails the first SG scan operation, performs a second SG scan operation on the memory portion, the second SG scan operation having different verification operations than the first SG scan operation. At operation 406, the media operations manager 142 selectively performs a second type of erase operation on the memory portion based on a result of performing the second SG scan operation on the memory portion.

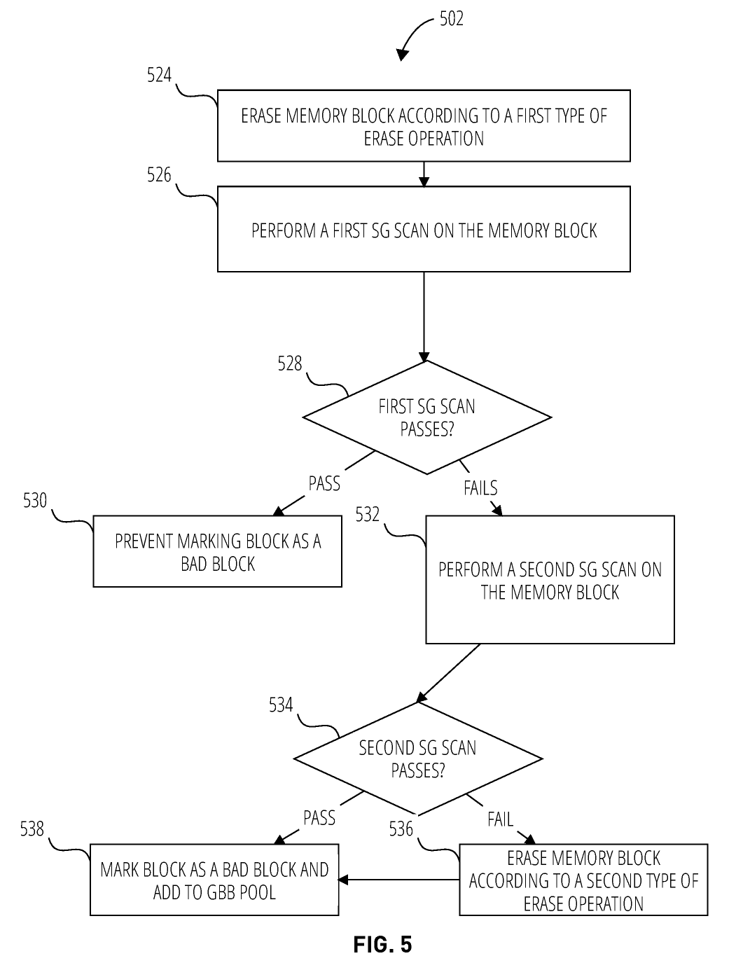

FIG. 5 illustrates a diagram 502 of operations performed using the media operations manager 142, in accordance with some examples. The method or process of diagram 502 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 502 is performed by the memory sub-system controller 115, local media controllers 135, and/or subcomponents of the memory sub-system controller 115 and/or local media controllers 135 of FIG. 1. In these examples, the method or process of diagram 502 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 5, the method begins at operation 524 where the media operations manager 142 performs an erase operation on a memory block according to a first type of erase operation. At operation 526, the media operations manager 142 performs a first SG scan on the memory block to evaluate its condition.

At operation 528, the media operations manager 142 determines whether the first SG scan passes or fails. If the first SG scan passes, the process moves to operation 530 where the media operations manager 142 prevents marking the block as a bad block. If the first SG scan fails, the process continues to operation 532 where the media operations manager 142 performs a second SG scan on the memory block with different verification criteria than the first SG scan.

At operation 534, the media operations manager 142 evaluates whether the second SG scan passes or fails. If the second SG scan passes, the process moves to operation 538 where the media operations manager 142 marks the block as a bad block and adds it to the grown bad block (GBB) pool without performing a second type of erase operation. If the second SG scan fails, the process continues to operation 536 where the media operations manager 142 performs a second type of erase operation on the memory block. The second type of erase operation can be a special erase option that programs the block to a slightly programmed state to prevent leakage current from impacting other blocks. After the second type of erase operation is complete, the process moves to operation 538 where the media operations manager 142 marks the block as a bad block and adds it to the GBB pool.

This flow ensures that special erase operations are performed only when necessary based on the results of both SG scans, optimizing system performance while maintaining reliability.

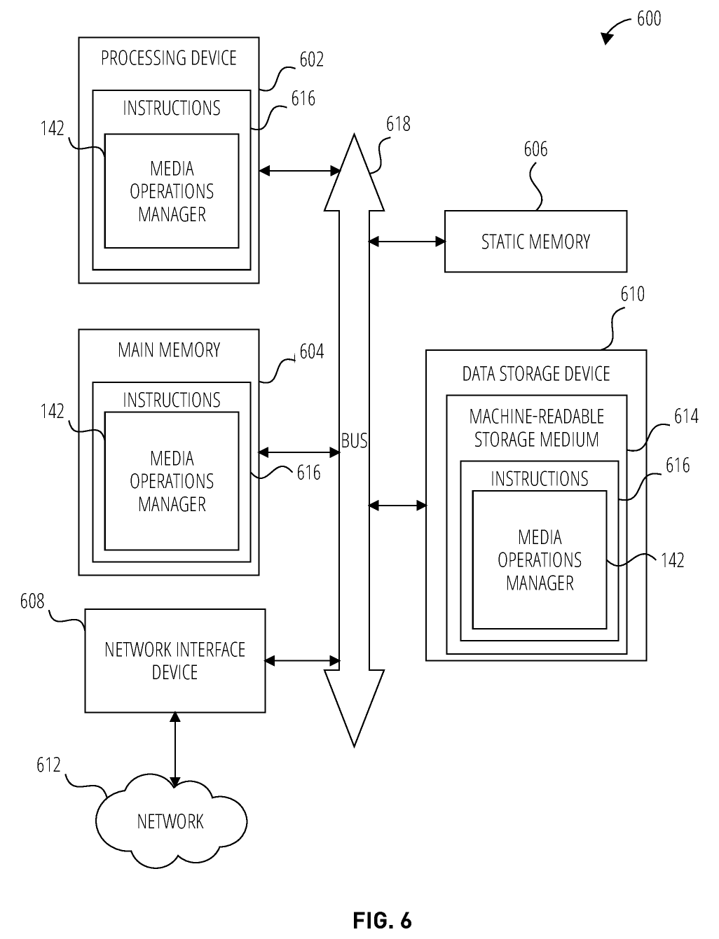

FIG. 6 illustrates an example machine in the form of a computer system 600 within which a set of instructions can be executed for causing the machine to perform any one or more of the methodologies discussed herein. In some examples, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., ROM, flash memory, DRAM such as SDRAM or Rambus DRAM (RDRAM), etc.), a static memory 606 (e.g., flash memory, static random access memory (SRAM), etc.), and a data storage device 610, which communicate with each other via a bus 618.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application-specific integrated circuit (ASIC), a field programmable gate array (FPGA), a digital signal processor (DSP), a network processor, or the like. The processing device 602 is configured to execute instructions 616 for performing the operations and steps discussed herein. The computer system 600 can further include a network interface device 608 to communicate over a network 612.

The data storage device 610 can include a machine-readable storage medium 614 (also known as a computer-readable medium) on which is stored one or more sets of instructions 616 or software embodying any one or more of the methodologies or functions described herein. The instructions 616 can also reside, completely or at least partially, within the main memory 604 and/or within the processing device 602 during execution thereof by the computer system 600, the main memory 604 and the processing device 602 also constituting machine-readable storage media. The machine-readable storage medium 614, data storage device 610, and/or main memory 604 can correspond to the memory sub-system 110 of FIG. 1.

In one example, the instructions 616 include instructions to implement functionality corresponding to providing block failure protection for a zone memory sub-system as described herein. While the machine-readable storage medium 614 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1. A system comprising: a memory device; and a processing device, operatively coupled to the memory device, configured to perform operations comprising: performing a first select gate (SG) scan operation on a memory portion of the memory device that has been erased according to a first type of erase operation; in response to determining that the memory portion fails the first SG scan operation, performing a second SG scan operation on the memory portion, the second SG scan operation having different verification operations than the first SG scan operation; and selectively performing a second type of erase operation on the memory portion based on a result of performing the second SG scan operation on the memory portion.

Example 2. The system of Example 1, wherein the different verification operations comprise at least one of a smaller threshold number of passing memory cells for passing the second SG scan operation or a different read threshold voltage applied to the memory portion.

Example 3. The system of Example 2, wherein the first SG scan operation comprises: applying a first verify voltage level to the memory portion; reading data from the memory portion in response to applying the first verify voltage level; measuring a number of memory cells that are successfully read as part of reading the data; comparing the number of memory cells to a first threshold number; and determining whether the memory portion fails the first SG scan operation in response to comparing that the number of memory cells to the first threshold number.

Example 4. The system of Example 3, wherein the second SG scan operation comprises: applying a second verify voltage level to the memory portion, the second verify voltage level being lower than the first verify voltage level; reading additional data from the memory portion in response to applying the second verify voltage level; measuring an additional number of memory cells that are successfully read as part of reading the additional data; comparing the additional number of memory cells to a second threshold number; and determining that the memory portion fails the second SG scan operation in response to determining that the additional number of memory cells fails to transgress the second threshold number.

Example 5. The system of any one of Examples 1-4, wherein the first type of erase operation leaves none of the memory portion in a programmed state, and wherein the second type of erase operation comprises a special erase operation that programs a specified set of regions of the memory portion into a programmed state.

Example 6. The system of any one of Examples 1-6, the operations comprising: determining that the memory portion passes the second SG scan operation; and in response to determining that the memory portion passes the second SG scan operation, categorizing the memory portion as a grown bad block (GBB) without performing the second type of erase operation.

Example 7. The system of any one of Examples 1-6, the operations comprising: determining that the memory portion fails the second SG scan operation; performing the second type of erase operation on the memory portion in response to determining that the memory portion fails the second SG scan operation; and in response to performing the second type of erase operation on the memory portion, categorizing the memory portion as a grown bad block (GBB).

Example 8. The system of any one of Examples 1-7, the operations comprising: adjusting the verification operations of the second SG scan based on a current temperature of the memory device.

Example 9. The system of Example 8, the operations comprising: storing a lookup table that associates different ranges of temperatures to different factors, a first entry in the lookup table associates a first range of temperatures to a first factor, a second entry in the lookup table associates a second range of temperatures to a second factor; and adjusting the verification operations by retrieving an adjustment factor from the lookup table.

Example 10. The system of any one of Examples 8-9, the operations comprising: adjusting the verification operations by calculating a ratio between a base temperature and the current temperature

Example 11. The system of Example 10, the operations comprising: selecting a factor from a lookup table based on the ratio; and adjusting a verify level used by the second SG scan operation using the selected factor.

Example 12. The system of any one of Examples 10-11, the operations comprising: selecting a factor from a lookup table based on the ratio; and adjusting a minimum number of passing memory cells used by the second SG scan operation using the selected factor.

Example 13. The system of any one of Examples 1-12, the operations comprising: skipping the second type of erase operation when the memory portion passes the second SG scan operation.

Example 14. The system of any one of Examples 1-13, the operations comprising: performing the second type of erase operation in response to determining that the memory portion fails the first SG scan operation and the second SG scan operation.

Example 15. The system of any one of Examples 1-14, the operations comprising: adjusting both a verify voltage level and a threshold number of passing cells for the second SG scan operation based on a temperature ratio between a current operating temperature and a base temperature of the memory device.

Example 16. The system of any one of Examples 1-15, wherein the memory device comprises a three-dimensional (3D) NAND device.

Example 17. The system of Example 16, wherein the memory portion comprises a block of the 3D NAND device.

Example 18. The system of any one of Examples 1-17, wherein the second type of erase operation programs the memory portion to prevent leakage current from impacting operations of other memory portions.

Example 19. At least one non-transitory machine-readable storage medium comprising instructions that, when executed by a processing device, cause the processing device to perform operations comprising: performing a first select gate (SG) scan operation on a memory portion of a memory device that has been erased according to a first type of erase operation; in response to determining that the memory portion fails the first SG scan operation, performing a second SG scan operation on the memory portion, the second SG scan operation having different verification operations than the first SG scan operation; and selectively performing a second type of erase operation on the memory portion based on a result of performing the second SG scan operation on the memory portion.

Example 20. A method comprising: performing a first select gate (SG) scan operation on a memory portion of a memory device that has been erased according to a first type of erase operation; in response to determining that the memory portion fails the first SG scan operation, performing a second SG scan operation on the memory portion, the second SG scan operation having different verification operations than the first SG scan operation; and selectively performing a second type of erase operation on the memory portion based on a result of performing the second SG scan operation on the memory portion.

The term “coupled with” generally refers to a connection between components, which can be an indirect communicative connection or direct communicative connection (e.g., without intervening components), whether wired or wireless, including connections such as electrical, optical, magnetic, and the like.

“System data” as used herein refers to data that is created and/or maintained by the memory sub-system for performing operations in response to host requests and for media management.

“User data” as used herein generally refers to host data and garbage collection data.

"Grown bad block (GBB)" refers to a memory block that has been retired from normal operation due to Select Gate (SG) scan failures or other failures.

“Retiring” as used herein refers to the process of removing NAND blocks from normal operation when they fail certain quality checks, specifically Select Gate (SG) scan tests.

"SG scan" refers to a periodic monitoring process that checks the Select Gate voltage threshold (VT) levels in NAND blocks. The scan reads data from cells using specific verify levels to determine if the number of cells passing that level exceeds a defined threshold. The process can involve applying a verify voltage level to the wordline; reading how many cells pass this voltage threshold; comparing the count of passing cells against a predetermined threshold; and determining pass/fail status based on whether enough cells meet the criteria. The primary purpose of SG scan is to monitor if Select Gate VTs remain within a designated safe range defined for normal NAND block operations. If VTs fall outside this safe range, the scan is marked as failed, which can trigger additional operations before block retirement.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

1. A system comprising:
a memory device; and
a processing device, operatively coupled to the memory device, configured to perform operations comprising:
performing a first select gate (SG) scan operation on a memory portion of the memory device that has been erased according to a first type of erase operation;
in response to determining that the memory portion fails the first SG scan operation, performing a second SG scan operation on the memory portion, the second SG scan operation having different verification operations than the first SG scan operation; and
selectively performing a second type of erase operation on the memory portion based on a result of performing the second SG scan operation on the memory portion.

2. The system of claim 1, wherein the different verification operations comprise at least one of a smaller threshold number of passing memory cells for passing the second SG scan operation or a different read threshold voltage applied to the memory portion.

3. The system of claim 2, wherein the first SG scan operation comprises:
applying a first verify voltage level to the memory portion;
reading data from the memory portion in response to applying the first verify voltage level;
measuring a number of memory cells that are successfully read as part of reading the data;
comparing the number of memory cells to a first threshold number; and
determining whether the memory portion fails the first SG scan operation in response to comparing that the number of memory cells to the first threshold number.

4. The system of claim 3, wherein the second SG scan operation comprises:
applying a second verify voltage level to the memory portion, the second verify voltage level being lower than the first verify voltage level;
reading additional data from the memory portion in response to applying the second verify voltage level;
measuring an additional number of memory cells that are successfully read as part of reading the additional data;
comparing the additional number of memory cells to a second threshold number; and
determining that the memory portion fails the second SG scan operation in response to determining that the additional number of memory cells fails to transgress the second threshold number.

5. The system of claim 1, wherein the first type of erase operation leaves none of the memory portion in a programmed state, and wherein the second type of erase operation comprises a special erase operation that programs a specified set of regions of the memory portion into a programmed state.

6. The system of claim 1, the operations comprising:
determining that the memory portion passes the second SG scan operation; and
in response to determining that the memory portion passes the second SG scan operation, categorizing the memory portion as a grown bad block (GBB) without performing the second type of erase operation.

7. The system of claim 1, the operations comprising:
determining that the memory portion fails the second SG scan operation;
performing the second type of erase operation on the memory portion in response to determining that the memory portion fails the second SG scan operation; and
in response to performing the second type of erase operation on the memory portion, categorizing the memory portion as a grown bad block (GBB).

8. The system of claim 1, the operations comprising:
adjusting the verification operations of the second SG scan based on a current temperature of the memory device.

9. The system of claim 8, the operations comprising:
storing a lookup table that associates different ranges of temperatures to different factors, a first entry in the lookup table associates a first range of temperatures to a first factor, a second entry in the lookup table associates a second range of temperatures to a second factor; and
adjusting the verification operations by retrieving an adjustment factor from the lookup table.

10. The system of claim 8, the operations comprising:
adjusting the verification operations by calculating a ratio between a base temperature and the current temperature

11. The system of claim 10, the operations comprising:
selecting a factor from a lookup table based on the ratio; and
adjusting a verify level used by the second SG scan operation using the selected factor.

12. The system of claim 10, the operations comprising:
selecting a factor from a lookup table based on the ratio; and
adjusting a minimum number of passing memory cells used by the second SG scan operation using the selected factor.

13. The system of claim 1, the operations comprising:
skipping the second type of erase operation when the memory portion passes the second SG scan operation.

14. The system of claim 1, the operations comprising:
performing the second type of erase operation in response to determining that the memory portion fails the first SG scan operation and the second SG scan operation.

15. The system of claim 1, the operations comprising:
adjusting both a verify voltage level and a threshold number of passing cells for the second SG scan operation based on a temperature ratio between a current operating temperature and a base temperature of the memory device.

16. The system of claim 1, wherein the memory device comprises a three-dimensional (3D) NAND device.

17. The system of claim 16, wherein the memory portion comprises a block of the 3D NAND device.

18. The system of claim 1, wherein the second type of erase operation programs the memory portion to prevent leakage current from impacting operations of other memory portions.

19. At least one non-transitory machine-readable storage medium comprising instructions that, when executed by a processing device, cause the processing device to perform operations comprising:
performing a first select gate (SG) scan operation on a memory portion of a memory device that has been erased according to a first type of erase operation;
in response to determining that the memory portion fails the first SG scan operation, performing a second SG scan operation on the memory portion, the second SG scan operation having different verification operations than the first SG scan operation; and
selectively performing a second type of erase operation on the memory portion based on a result of performing the second SG scan operation on the memory portion.

20. A method comprising:
performing a first select gate (SG) scan operation on a memory portion of a memory device that has been erased according to a first type of erase operation;
in response to determining that the memory portion fails the first SG scan operation, performing a second SG scan operation on the memory portion, the second SG scan operation having different verification operations than the first SG scan operation; and
selectively performing a second type of erase operation on the memory portion based on a result of performing the second SG scan operation on the memory portion.
